(19) United States
(12) Patent Application Publication
(10) Pub. No.: US 2026/0296338 A1
(43) Pub. Date: Oct. 1, 2026

(54) ELECTRICAL COMPONENT PROTECTION STRUCTURE AND VEHICLE

(71) Applicant: HONDA MOTOR CO., LTD., Tokyo (JP)

(72) Inventors: Kunihiro Kai, Tokyo (JP); Tomohiko Yashiro, Tokyo (JP); Shogo Matsumoto, Tokyo (JP)

(21) Appl. No.: 19/555,960

(22) Filed: Mar. 4, 2026

(30) Foreign Application Priority Data
Mar. 28, 2025 (JP) 2025-055045

(51) Int. Cl. B60R 16/02; H05K 5/02

(52) U.S. Cl. CPC B60R 16/0215; H05K 5/0204; H05K 5/0217

(57) ABSTRACT

An electrical component protection structure includes a support member that includes a peripheral wall surrounding an electrical component and is configured to support the electrical component, and a stay connected to the support member and mounted to a mounting target, wherein the support member includes a wide portion protruding toward the stay from a partial wall portion, which is a wall portion of the peripheral wall that faces the stay.

### CROSS-REFERENCE TO RELATED APPLICATIONS

This application is based upon and claims the benefit of priority from Japanese Patent Application No. 2025-055045 filed on Mar. 28, 2025, the contents of which are incorporated herein by reference.

### BACKGROUND OF THE INVENTION

### Field of the Invention

The present disclosure relates to an electrical component protection structure and a vehicle.

### Description of the Related Art

JP 2019-071376 A discloses that a connector is exposed to the outside through an opening of a cover member and a flange portion is provided on the cover member to prevent water droplets from entering the opening.

### SUMMARY OF THE INVENTION

If the flange portion is provided on the cover member so as to cover the connector of the electrical component mounted on the vehicle, the size of the cover member becomes large and there may be a case where a restriction is imposed on the shape of the electrical component present around the connector. A compact waterproof structure is desired.

The present invention has the object of solving the aforementioned problem.

The first aspect of the present disclosure is an electrical component protection structure of the present disclosure includes a support member including a peripheral wall surrounding an electrical component and configured to support the electrical component, and a stay connected to the support member and mounted to a mounting target, wherein the support member includes a wide portion protruding toward the stay from a partial wall portion, which is a wall portion of the peripheral wall that faces the stay.

A second aspect of the present disclosure is a vehicle including the electrical component protection structure of the first aspect and an electrical component.

According to the present disclosure, a compact waterproof structure can be achieved.

The above and other objects, features, and advantages of the present invention will become more apparent from the following description when taken in conjunction with the accompanying drawings, in which a preferred embodiment of the present invention is shown by way of illustrative example.

### BRIEF DESCRIPTION OF THE DRAWINGS

FIG. 1 is a left side view of a saddle-riding type vehicle with an electrical component protection structure according to an embodiment;

FIG. 2 is a right side view showing a state in which the electrical component protection structure supporting an electrical component is fixed to a main frame;

FIG. 3 is a perspective view of the electrical component, a support member, and a stay;

FIG. 4 is a left side view of the electrical component protection structure supporting the electrical component;

FIG. 5 is a front view of the electrical component protection structure supporting the electrical component;

FIG. 6 is a plan view of the electrical component protection structure supporting the electrical component;

FIG. 7 is a bottom view of the electrical component protection structure supporting the electrical component;

FIG. 8 is a cross-sectional view taken along a line VIII-VIII of FIG. 4;

FIG. 9 is a left side view of the support member;

FIG. 10 is a partial cross-sectional view taken along a line X-X of FIG. 2;

FIG. 11 is a partial cross-sectional view showing the wiring of a harness;

FIGS. 12A, 12B, and 12C, are partial cross-sectional views showing other configuration examples of the support member;

FIGS. 13A, 13B and 13C are partial plan views showing other configuration examples of the support member; and

FIG. 14A is a left side view showing another configuration example of the support member, and FIG. 14B is a partial cross-sectional view showing another configuration example of the support member.

### DETAILED DESCRIPTION OF THE INVENTION

As explained below, according to the present disclosure, a compact waterproof structure can be achieved. That is, according to the present disclosure, an electrical component protection structure and a vehicle are provided that can appropriately protect an electrical component from liquid such as water without reducing a space around a connector or increasing the size of the electrical component.

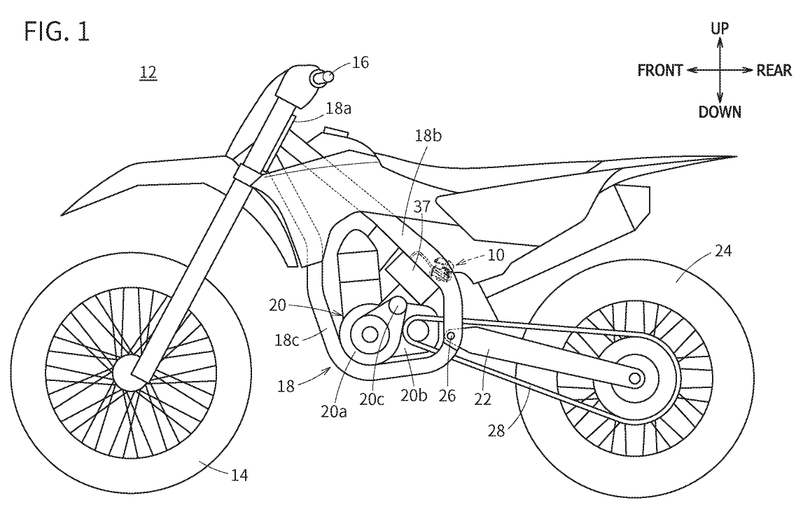

An electrical component protection structure 10 according to an embodiment will be described with reference to FIGS. 1 to 14B. FIG. 1 is a left side view of a saddle-riding type vehicle (vehicle) 12 with an electrical component protection structure 10. In the following description, the directions of the front, the rear, the left and the right, and the up and down will be described, with the direction in which the saddle-riding type vehicle 12 moves forward being designated as the front.

The saddle-riding type vehicle 12 is an off-road two-wheeled vehicle but is not limited to this. The saddle-riding type vehicle 12 may be an on-road two-wheeled vehicle. The saddle-riding type vehicle 12 may be any of various saddle-riding type vehicles such as unicycle, two-wheeled vehicle, three-wheeled vehicle, four-wheeled vehicle, and so on.

The saddle-riding type vehicle 12 includes a front wheel 14, handlebars 16, a vehicle body frame (mounting target) 18, a power unit 20, a swing arm 22, and a rear wheel 24.

The vehicle body frame 18 has a head pipe 18a, a pair of right and left main frames 18b, and a down frame 18c. The head pipe 18a constitutes a front end portion of the vehicle body frame 18. The head pipe 18a supports the front wheel 14 and the handlebars 16 in a steerable manner. The main frame 18b extends rearward from the head pipe 18a. A rear portion of the main frame 18b extends downward. Below the main frame 18b, the down frame 18c extends downward from the head pipe 18a. A rear end portion of the down frame 18c is connected to a rear end portion of the main frame 18b.

A pivot shaft 26 is connected to the rear end portions of the pair of left and right main frames 18b. The pivot shaft 26 extends in the vehicle width direction (left-right direction). A front end of the swing arm 22 is shaft-supported by the pivot shaft 26. The swing arm 22 extends rearward from the pivot shaft 26. A rear end portion of the swing arm 22 shaft-supports the rear wheel 24.

As shown in FIG. 1, the power unit 20 is positioned between the main frame 18b and the down frame 18c. The power unit 20 is supported by the main frame 18b and the down frame 18c. The power unit 20 includes an engine 20a, a transmission 20b, and a starter motor 20c. A chain 28 is bridged between the transmission 20b and the rear wheel 24. The power of the engine 20a is transmitted to the rear wheel 24 via the transmission 20b and the chain 28. The rear wheel 24 is rotated by the transmitted power to drive the saddle-riding type vehicle 12. As will be described later, the starter motor 20c can be used to start the engine 20a.

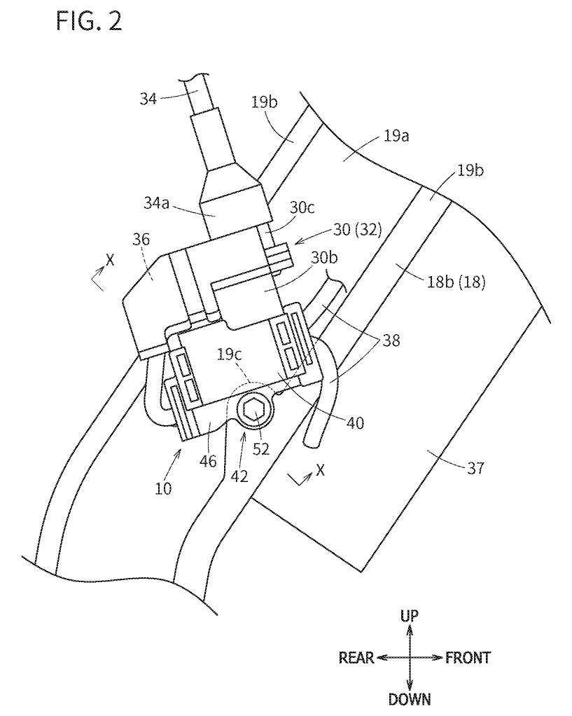

As shown in FIG. 2, the electrical component protection structure 10 is mount ed to the vehicle body frame 18. Specifically, the electrical component protection structure 10 is mount ed to an edge portion 19b of the main frame 18b constituting the vehicle body frame 18.

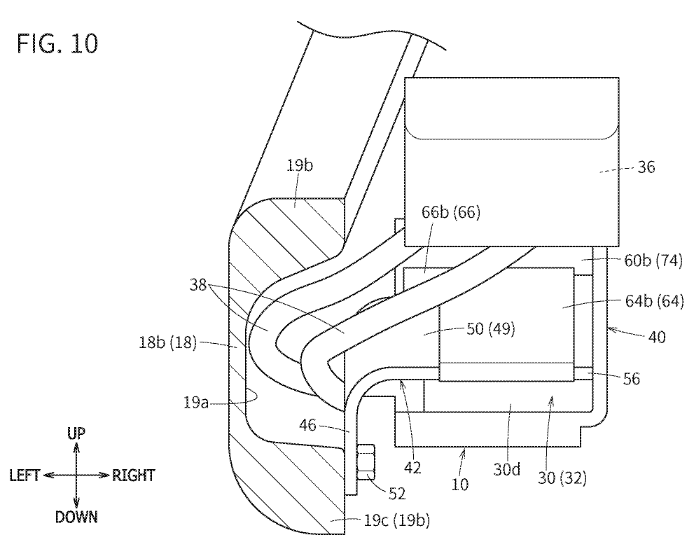

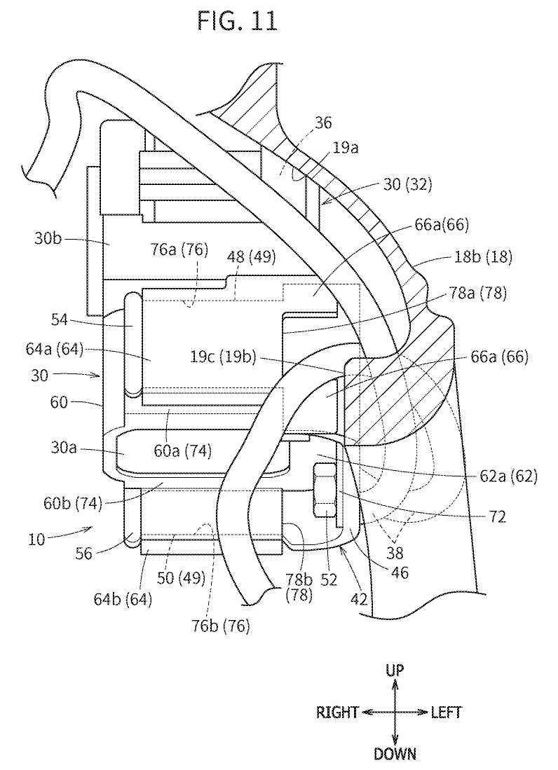

More specifically, at least the main frame 18b of the vehicle body frame 18 has a central portion 19a and an edge portion 19b. The central portion 19a is a central portion in the width direction of the main frame 18b. The edge portion 19b is an end portion in the width direction of the main frame 18b. The edge portions 19b are provided on both sides of the central portion 19a in the width direction of the main frame 18b. As shown in FIGS. 10 and 11, the central portion 19a projects more outward in the vehicle width direction than the edge portion 19b. The edge portion 19b projects more inward in the vehicle width direction than the central portion 19a.

As shown in FIG. 2, the electrical component protection structure 10 supports the electrical component 30. The electrical component protection structure 10 is mount ed to the vehicle body frame 18 on the inner side in the vehicle width direction in a manner so that the electrical component 30 overlaps the vehicle body frame 18 in the side view of FIG. 2. The electrical component protection structure 10 can be used to mount the electrical component 30 to the vehicle body frame 18 and to protect the electrical component 30.

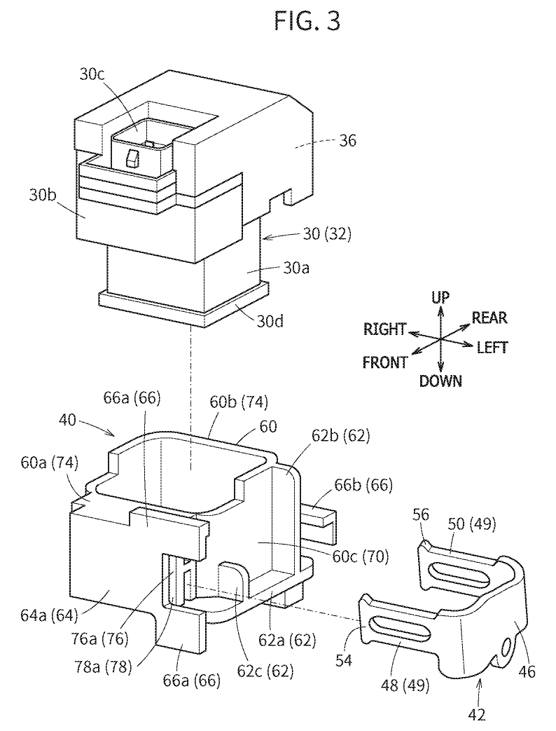

The electrical component 30 is a starter magnet relay 32. As shown in FIG. 3, the electrical component 30 has a rectangular lower portion 30a, a rectangular upper portion 30b, and a connector portion 30c.

In FIG. 3, for convenience of explanation, the electrical component 30, the support member 40, and the stay 42, which will be described later, are illustrated with the axial direction of the support member 40, which will be described later, being the up-down direction. Actually, as shown in FIG. 2, the electrical component protection structure 10 supports the electrical component 30 with the support member 40 and is mount ed to the vehicle body frame 18 in a state of being inclined along the vehicle body frame 18.

As shown in FIG. 3, a flange portion 30d is provided on an outer peripheral surface of the lower portion 30a. The flange portion 30d protrudes from a lower end portion of the lower portion 30a. The upper portion 30b is provided at the upper end of the lower portion 30a. The upper portion 30b protrudes more forward and in the vehicle width direction than the lower portion 30a. The connector portion 30c is provided on an upper surface of the upper portion 30b. The connector portion 30c can be connected to a harness-side connector 34a (see FIG. 2) provided at the distal end of a harness 34. A fuse 36 is provided inside the upper portion 30b. The fuse 36 is provided inside the upper portion 30b so as to be adjacent to the connector portion 30c. As shown in FIGS. 1 and 2, a battery 37 is mount ed to the main frame 18b. The harness 38 extends from the battery 37. The fuse 36 is interposed in the harness 34 that branches from the harness 38.

The starter magnet relay 32 is electrically connected to the starter motor 20c (see FIG. 1) via the harness 38. When power is supplied from the battery 37 to the starter motor 20c via the starter magnet relay 32, the starter motor 20c is driven to start the engine 20a.

As shown in FIG. 2, the electrical component protection structure 10 is mount ed to the edge portion 19b of the left main frame 18b. The electrical component protection structure 10 is mount ed to a portion of the edge portion 19b of the left main frame 18b, the portion being positioned on the inner side in the vehicle width direction. The electrical component protection structure 10 is mount ed to the main frame 18b in a manner so that the electrical component 30 overlaps the main frame 18b. Thus, it is possible to prevent the electrical component 30 from being hit by liquid such as water from the left direction. The main frame 18b extends obliquely downward toward the rear from the head pipe 18a. Therefore, the electrical component protection structure 10 is mount ed to the main frame 18b in a state of being inclined obliquely downward with respect to the front-rear direction so as to be along the main frame 18b.

The electrical component protection structure 10 includes the support member 40 and the stay 42.

As shown in FIG. 3, the stay 42 is a U-shaped member made of metal. The stay 42 has a mounted portion 46 and a fitted portion 49. The fitted portion 49 is a first fitted portion 48 and a second fitted portion 50.

As shown in FIG. 2, the mounted portion 46 is a plate-like portion extending along the front-rear direction. The mounted portion 46 is mounted to a mounting boss 19c provided on the edge portion 19b of the main frame 18b by a mounting member 52 such as a bolt.

FIGS. 10 and 11 illustrate the positional relationship among the main frame 18b, the stay 42, and the harness 38. The edge portion 19b and the mounting boss 19c of the main frame 18b project more inward in the vehicle width direction than the central portion 19a. The central portion 19a of the main frame 18b is more concave to the outside in the vehicle width direction than the edge portion 19b and the mounting boss 19c. As described above, the mounted portion 46 is mounted to the mounting boss 19c of the main frame 18b by the mounting member 52, whereby the stay 42 is mounted to the mounting boss 19c. Therefore, a space is created between the stay 42 mounted to the mounting boss 19c and the central portion 19a of the main frame 18b. In the present embodiment, the harness 38 is routed in this space. Thus, it is possible to prevent the harness 38 from contacting other members without providing any additional members. Moreover, it is possible to prevent, without providing any additional member, the harness 38 from being damaged by contacting flicked stones and obstacles during the traveling of the saddle-riding type vehicle 12.

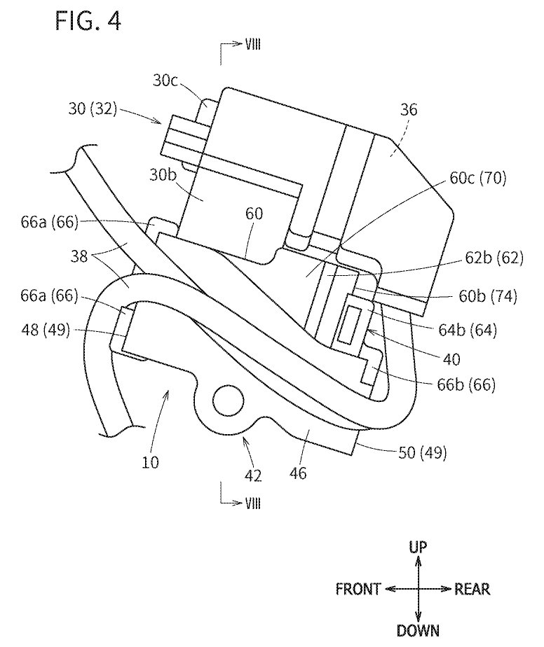

As shown in FIG. 2, since the electrical component protection structure 10 is inclined obliquely downward with respect to the front-rear direction, the mounted portion 46 is inclined obliquely downward as it goes rearward (see FIG. 4).

As shown in FIG. 3, the first fitted portion 48 extends rightward from a front end portion of the mounted portion 46. The width of the first fitted portion 48 in the short-side direction is smaller than the width of the mounted portion 46 in the short-side direction. The short-side direction of the first fitted portion 48 and the short-side direction of the mounted portion 46 are the axial direction of the support member 40. Part of the first fitted portion 48 has been subjected to a lightening process. A first locking portion 54 is provided at the distal end of the first fitted portion 48. The first locking portion 54 projects from the distal end of the first fitted portion 48 in the short-side direction of the first fitted portion 48.

The second fitted portion 50 extends rightward from a rear end portion of the mounted portion 46. The width of the second fitted portion 50 in the short-side direction is smaller than the width of the mounted portion 46 in the short-side direction. The short-side direction of the second fitted portion 50 is the axial direction of the support member 40. Part of the second fitted portion 50 has been subjected to a lightening process. A second locking portion 56 is provided at the distal end of the second fitted portion 50. The second locking portion 56 projects from the distal end of the second fitted portion 50 in the short-side direction of the second fitted portion 50.

As shown in FIGS. 4 to 7, the support member 40 can support the electrical component 30 in a state of being connected to the stay 42. The support member 40 is made of an elastic body such as rubber. As shown in FIG. 3, the support member 40 is a tubular member. The support member 40 has a peripheral wall 60, a plurality of wide portions 62, a plurality of mounting portions 64, and a plurality of protection portions 66.

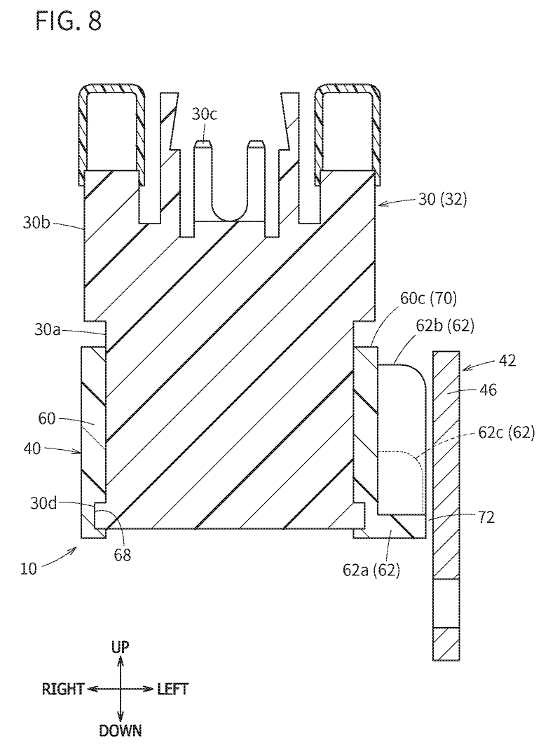

The peripheral wall 60 is the main body portion of the support member 40. The peripheral wall 60 is a rectangular tubular portion formed to surround the electrical component 30. Specifically, as shown in FIG. 8, the lower portion 30a of the electrical component 30 is inserted on the inner side of the peripheral wall 60. The peripheral wall 60 surrounds the lower portion 30a of the electrical component 30. An annular recess 68 is formed on the inner side of the peripheral wall 60. The flange portion 30d of the electrical component 30 is fitted into the recess 68. By the flange portion 30d being fitted into the recess 68, the electrical component 30 is supported by the support member 40 in a state where the lower portion 30a is surrounded by the peripheral wall 60.

As shown in FIG. 3, the peripheral wall 60 includes a front wall portion 60a, a rear wall portion 60b, and a left wall portion 60c. The front wall portion 60a is a wall portion on the front side of the peripheral wall 60. The rear wall portion 60b is a wall portion on the rear side of the peripheral wall 60. The left wall portion 60c is a wall portion on the left side of the peripheral wall 60. A front end portion of the left wall portion 60c is connected to the front wall portion 60a. A rear end portion of the left wall portion 60c is connected to the rear wall portion 60b.

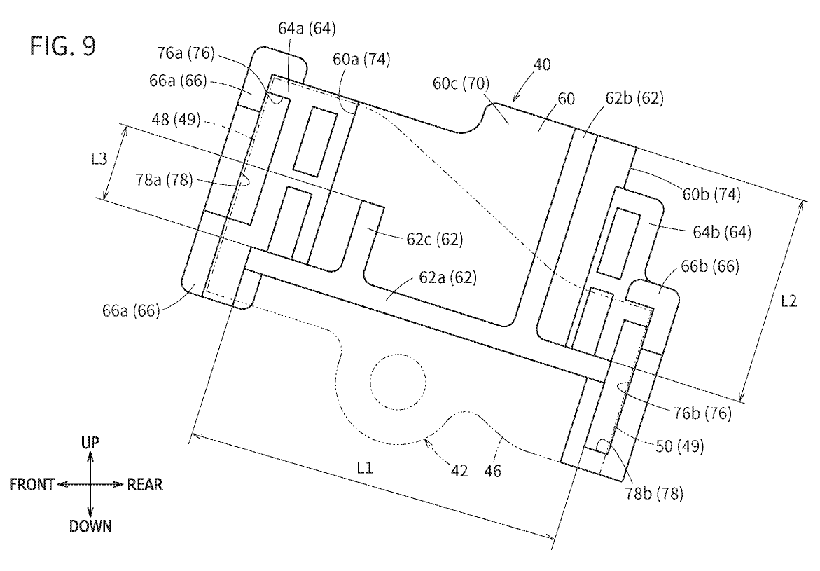

As shown in FIG. 8, a plurality of wide portions 62 project from a partial wall portion 70 toward the stay 42. The partial wall portion 70 is a wall portion of the peripheral wall 60 that faces the stay 42. The plurality of wide portions 62 are provided on the partial wall portion 70 in a manner so that a gap 72 is created between the wide portions 62 and the stay 42. As shown in FIG. 9, each of the plurality of wide portions 62 is provided at a different location on the partial wall portion 70.

As shown in FIG. 9, the extending directions of at least two of the wide portions 62 among the plurality of wide portions 62 are directions intersecting with each other. As shown in FIG. 8, the extending direction of at least one of the wide portions 62 and the extending direction of the stay 42 are directions intersecting each other. The extending direction of the wide portion 62 includes at least one of the longitudinal direction and the short-side direction of the wide portion 62. The extending direction of the stay 42 includes at least one of the longitudinal direction and the short-side direction of the stay 42.

As shown in FIG. 9, the total longitudinal lengths of at least two of the wide portions 62 are different from each other.

More specifically, as shown in FIG. 3, the partial wall portion 70 is the left wall portion 60c. As shown in FIG. 8, in the state where the support member 40 is mounted to the stay 42, the partial wall portion 70 faces the mounted portion 46 of the stay 42 in the vehicle width direction. The plurality of wide portions 62 are ribs projecting leftward from the partial wall portion 70 toward the mounted portion 46. As shown in FIG. 9, the plurality of wide portions 62 includes a first wide portion 62a, a second wide portion 62b, and a third wide portion 62c.

As shown in FIG. 8, the first wide portion 62a projects leftward from the lower end portion of the partial wall portion 70. As shown in FIG. 9, the first wide portion 62a extends linearly along the lower end portion of the partial wall portion 70 in a side view. Therefore, the longitudinal direction of the first wide portion 62a (first longitudinal direction) is a direction along the lower end portion of the partial wall portion 70. The short-side direction of the first wide portion 62a is the left direction. By providing the first wide portion 62a, it is possible to prevent liquid such as water from hitting the electrical component 30 from the direction (downward) opposite the electrical component 30 across the first wide portion 62a.

As shown in FIG. 3, the second wide portion 62b projects leftward from a rear portion of the partial wall portion 70. As shown in FIG. 9, the second wide portion 62b extends linearly so as to be orthogonal to the first wide portion 62a in a side view. Therefore, the longitudinal direction of the second wide portion 62b (second longitudinal direction) is a direction orthogonal to the first longitudinal direction. The short-side direction of the second wide portion 62b is the left direction. The lower end of the second wide portion 62b is connected to the first wide portion 62a. An upper end portion of the second wide portion 62b is positioned at the upper end of the partial wall portion 70. By providing the second wide portion 62b, it is possible to prevent liquid such as water from hitting the electrical component 30 from the rear.

As shown in FIG. 3, the third wide portion 62c projects leftward from a front portion of the partial wall portion 70. As shown in FIG. 9, in a side view, the third wide portion 62c extends linearly, being orthogonal to the first wide portion 62a and parallel to the second wide portion 62b. Therefore, the longitudinal direction of the third wide portion 62c (third longitudinal direction) is a direction orthogonal to the first longitudinal direction and parallel to the second longitudinal direction. The short-side direction of the third wide portion 62c is the left direction. A lower end of the third wide portion 62c is connected to the first wide portion 62a. By providing the third wide portion 62c, it is possible to prevent liquid such as water from hitting the electrical component 30 from the front.

The total length L1 of the first wide portion 62a in the first longitudinal direction is longer than the total length L2 of the second wide portion 62b in the second longitudinal direction (L1 > L2). The total length L1 of the first wide portion 62a in the first longitudinal direction is longer than the total length L3 of the third wide portion 62c in the third longitudinal direction (L1 > L3). Further, the total length L2 of the second wide portion 62b in the second longitudinal direction is longer than the total length L3 of the third wide portion 62c in the third longitudinal direction (L2 > L3). Accordingly, the total lengths in the longitudinal direction become shorter in the order of the first wide portion 62a, the second wide portion 62b and the third wide portion 62c (L1 > L2 > L3). By changing the total length of the wide portion 62 in the longitudinal direction according to a formation location of the wide portion 62, it is possible to enhance the waterproof effect on the electrical component 30 with the minimum space required and to reduce the weight of the support member 40.

As shown in FIG. 8, a slight gap 72 is formed between the mounted portion 46 of the stay 42 and the first wide portion 62a, the second wide portion 62b, and the third wide portion 62c. By providing the gap 72, it is possible to let foreign matters such as mud and dust present in the space above the first wide portion 62a fall downward through the gap 72. Thereby, foreign matters such as mud and dust can be prevented from accumulating. The size of the gap 72 is, for example, about 1 mm but is not limited to this.

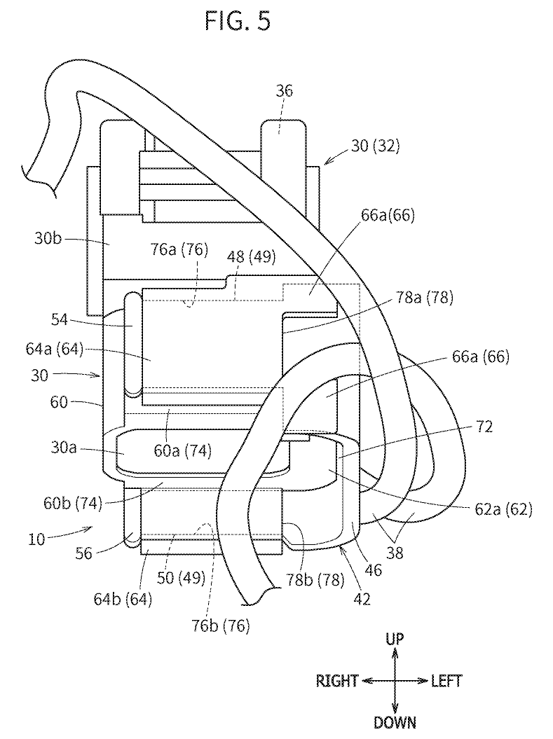

As shown in FIGS. 5 to 7, the support member 40 is mounted to the stay 42 by fitting the fitted portions 49 (first fitted portion 48, second fitted portion 50) into the mounting portions 64. As shown in FIG. 3, the mounting portion 64 is provided on an adjacent wall portion 74. The adjacent wall portion 74 is a wall portion of the peripheral wall 60 that is adjacent to the partial wall portion 70. The mounting portion 64 is formed with a fitting hole 76 into which the fitted portion 49 is fitted. The protection portion 66 is provided on an opening 78 side of the fitting hole 76 at the mounting portion 64. As shown in FIGS. 4 to 6, in a state where the fitted portion 49 is fitted into the fitting hole 76, the protection portion 66 covers a portion of the stay 42 that is positioned further outside in the axial direction of the peripheral wall 60 than the opening 78.

As shown in FIGS. 3 to 5, the adjacent wall portion 74 is the front wall portion 60a and the rear wall portion 60b. The plurality of mounting portions 64 include a first mounting portion 64a and a second mounting portion 64b. As shown in FIG. 9, the fitting holes 76 are a first fitting hole 76a and a second fitting hole 76b. The opening 78 is a first opening 78a and a second opening 78b.

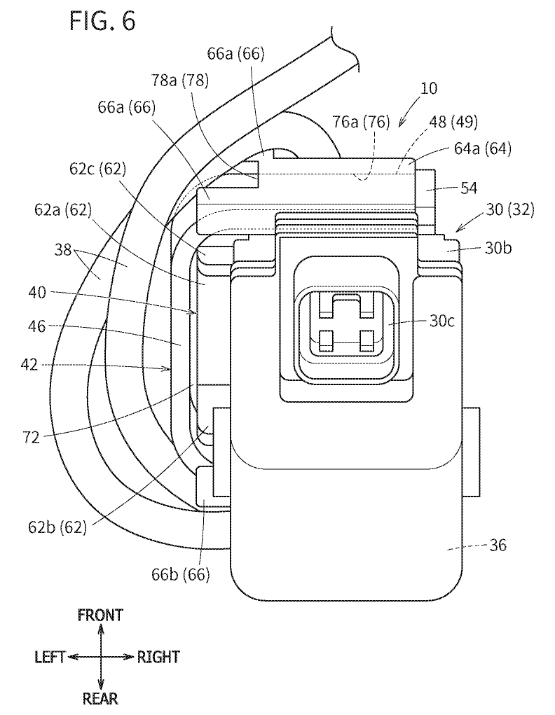

As shown in FIG. 3, the first mounting portion 64a is provided on the front wall portion 60a. The first opening 78a is formed in the left side surface of the first mounting portion 64a. The first fitting hole 76a is formed in the first mounting portion 64a. The first fitting hole 76a extends rightward from the first opening 78a. As shown in FIGS. 5 and 6, the first fitting hole 76a penetrates the first mounting portion 64a in the vehicle width direction. The first fitted portion 48 is inserted into the first fitting hole 76a through the first opening 78a. When the first fitted portion 48 is fitted into the first fitting hole 76a, the first locking portion 54 projects rightward from the first fitting hole 76a and is engaged with a right side surface of the first mounting portion 64a. When the first fitted portion 48 is fitted into the first fitting hole 76a, the front end portion of the mounted portion 46 is engaged with a left side surface of the first mounting portion 64a so as to close the first opening 78a.

The first fitting hole 76a is not limited to a through hole that penetrates the first mounting portion 64a in the vehicle width direction. The first fitting hole 76a may be a hole portion with a bottom that is depressed rightward from the first opening 78a. In this case, the first locking portion 54 is engaged with an engagement hole (not shown) formed at a back side of the first fitting hole 76a.

As shown in FIG. 9, the second mounting portion 64b is provided on the rear wall portion 60b. The second opening 78b is formed in a left side surface of the second mounting portion 64b. The second fitting hole 76b is formed in the second mounting portion 64b. The second fitting hole 76b extends rightward from the second opening 78b. As shown in FIG. 5, the second fitting hole 76b penetrates the second mounting portion 64b in the vehicle width direction. The second fitted portion 50 is inserted into the second fitting hole 76b via the second opening 78b. When the second fitted portion 50 is fitted into the second fitting hole 76b, the second locking portion 56 projects rightward from the second fitting hole 76b and is engaged with a right side surface of the second mounting portion 64b. When the second fitted portion 50 is fitted into the second fitting hole 76b, the rear end portion of the mounted portion 46 is engaged with a left side surface of the second mounting portion 64b so as to close the second opening 78b.

The second fitting hole 76b is not limited to a through hole that penetrates the second mounting portion 64b in the vehicle width direction. The second fitting hole 76b may be a hole portion with a bottom that is depressed rightward from the second opening 78b. In this case, the second locking portion 56 is engaged with an engagement hole (not shown) formed at a back side of the second fitting hole 76b.

Since the support member 40 is mounted to the stay 42 by fitting the fitted portion 49 into the mounting portion 64 in this way, the electrical component 30 can be mounted to the main frame 18b with a simple configuration.

As shown in FIG. 9, multiple protection portions 66 include multiple first protection portions 66a and a second protection section 66b.

As shown in FIG. 3, the first protection portions 66a are provided on the first opening 78a side of the first fitting hole 76a at the first mounting portion 64a. As shown in FIGS. 4 and 5, one first protection portion 66a of the first protection portions 66a projects leftward from an upper side portion of the front end portion of the first mounting portion 64a so as to cover an upper side portion of the front end portion of the mounted portion 46. As shown in FIG. 4, in the side view, the one first protection portion 66a covers the upper side portion of the front end portion of the mounted portion 46 from the front and the upper side. As shown in FIGS. 4 and 5, another first protection portion 66a of the first protection portions 66a projects leftward from a lower side portion of the front end portion of the first mounting portion 64a so as to cover a lower side portion of the front end portion of the mounted portion 46. As shown in FIG. 4, in the side view, the other first protection portion 66a covers the lower side portion of the front end portion of the mounted portion 46 from the front.

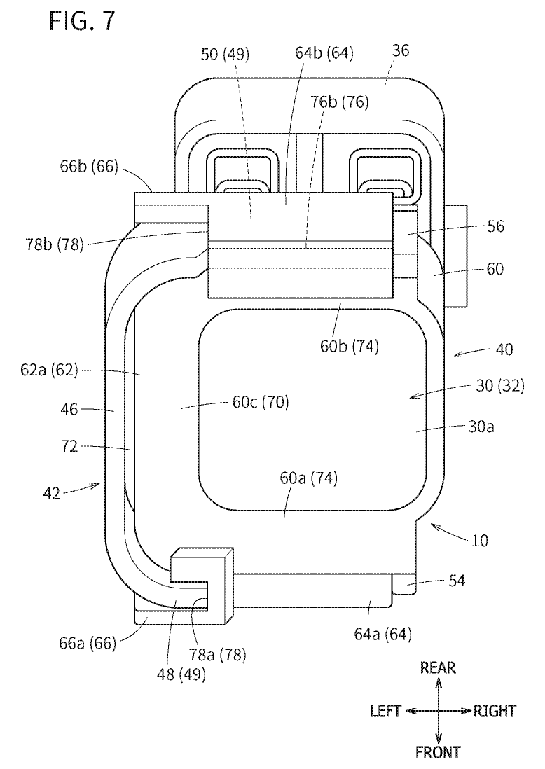

As shown in FIG. 9, the second protection portion 66b is provided on the second opening 78b side of the second fitting hole 76b at the second mounting portion 64b. As shown in FIG. 7, the second protection portion 66b projects leftward from an upper portion of the rear end portion of the second mounting portion 64b so as to cover an upper portion of the rear end portion of the mounted portion 46. As shown in FIG. 4, in the side view, the second protection portion 66b covers the upper side portion of the rear end portion of the mounted portion 46 from the rear and the upper side.

Thus, the protection portion 66 covers a portion of the stay 42 that is more upward and downward than the opening 78. Thus, the stay 42 or the harnesses 34, 38 existing around the stay 42 can be prevented from being damaged by displacement of the stay 42 or the harnesses 34, 38.

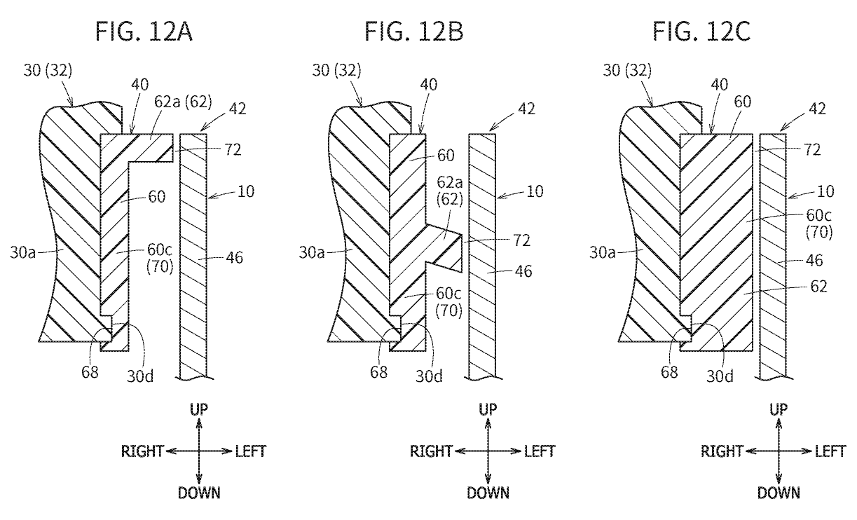

The electrical component protection structure 10 according to the present embodiment is not limited to the above embodiment. It can be configured as shown in FIGS. 12A to 14B.

In FIG. 12A, the first wide portion 62a is provided at the upper end portion of the partial wall portion 70.

In FIG. 12B, the first wide portion 62a is provided between the upper and lower end portions of the partial wall portion 70. The first wide portion 62a extends obliquely downward toward the stay 42 from the partial wall portion 70.

In FIG. 12C, the wide portion 62 extends from between the upper and lower end portions of the partial wall portion 70 toward the stay 42. The wide portion 62 extends toward the stay 42 over the entire area of the partial wall portion 70. Alternatively, the wide portion 62 may extend from between the upper and lower end portions of the partial wall portion 70 toward the stay 42 as the second wide portion 62b (see FIG. 3) does.

Any of the configurations in FIGS. 12A to 12C can prevent liquid such as water from hitting the electrical component 30 from the lower direction. In addition, in the configuration of FIG. 12B, since the first wide portion 62a extends obliquely downward, foreign matters such as mud and dust can efficiently fall downward through the gap 72.

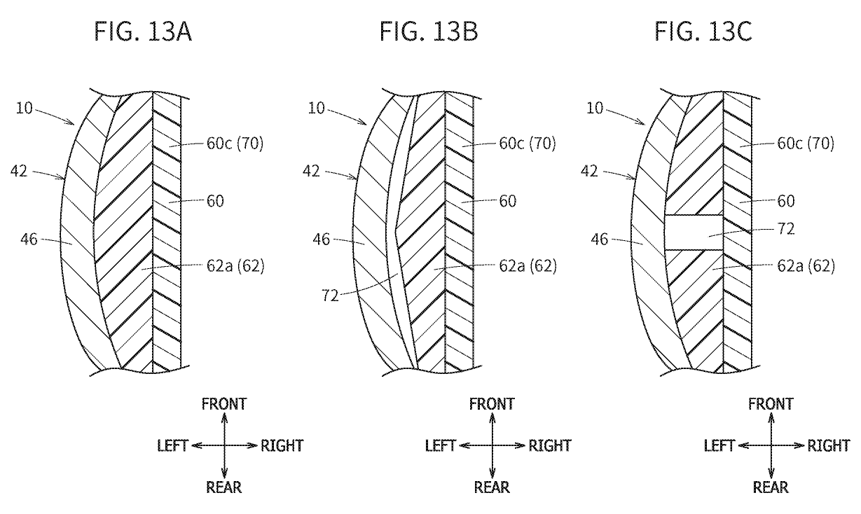

In FIG. 13A, the first wide portion 62a projects leftward from the partial wall portion 70 so as to fill the gap 72 (see FIG. 6) between the partial wall portion 70 and the mounted portion 46.

In FIG. 13B, the gap 72 is formed between the first wide portion 62a and the mounted portion 46 in such a way that the width of the partial wall portion 70 in the short-side direction changes in the longitudinal direction of the partial wall portion 70. In this case, the left side surface of the first wide portion 62a is formed in a V-shape in plan view.

In FIG. 13C, the front portion and the rear portion of the first wide portion 62a project leftward from the partial wall portion 70. The gap 72 is formed between the front portion and the rear portion of the first wide portion 62a.

In this embodiment, the gap 72 may be formed by combining the configurations of FIGS. 13B and 13C. In the present embodiment, the wide portion 62 may be formed by forming, into an arbitrary shape such as a wave shape, a surface of the partial wall portion 70 that faces the mounted portion 46.

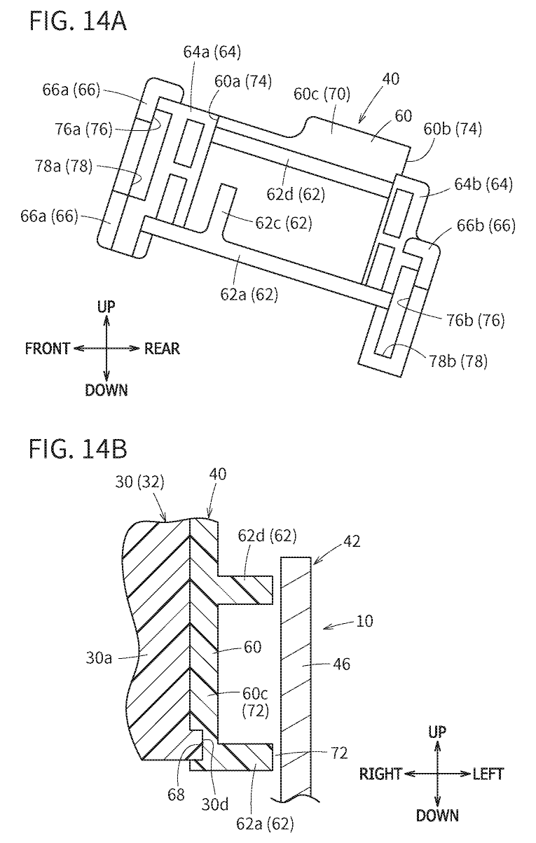

In FIGS. 14A and 14B, the multiple wide portions 62 further include a fourth wide portion 62d. The fourth wide portion 62d is formed on an upper portion of the partial wall portion 70. The fourth wide portion 62d is formed parallel to the first wide portion 62a. The partial wall portion 70 is not provided with the second wide portion 62b (see FIG. 3).

The following supplementary notes are further disclosed in relation to the above-described embodiment.

### Supplementary Note 1

An electrical component protection structure (10) of the present disclosure includes a support member (40) including a peripheral wall (60) surrounding an electrical component (30) and configured to support the electrical component, and a stay (42) connected to the support member and mounted to a mounting target (18), wherein the support member includes a wide portion (62) protruding toward the stay from a partial wall portion (70), which is a wall portion of the peripheral wall that faces the stay.

According to this configuration, the electrical component can be suitably protected from liquid such as water. More specifically, it is possible to prevent liquid such as water from hitting the electrical component from the direction opposite the electrical component across the wide portion. Moreover, it is possible to prevent liquid such as water from hitting the electrical component from the direction opposite the electrical component across the stay. Therefore, it is possible to prevent liquid such as water from hitting the electrical component from at least two directions.

### Supplementary Note 2

In the electrical component protection structure described in Supplementary Note 1, the wide portion may be provided on the partial wall portion in a manner so that a gap (72) is created between the wide portion and the stay.

With this configuration, foreign matters such as mud and dust present in a space above the wide portion fall downward through the gap. Thus, it is possible to prevent liquid such as water from hitting the electrical component from below and also prevent foreign matters such as mud and dust from accumulating.

### Supplementary Note 3

In the electrical component protection structure according to Supplementary Note 1 or 2, the support member may include a plurality of the wide portions, and each of the plurality of the wide portions may be provided at a different position of the partial wall portion.

According to this configuration, it is possible to prevent liquid such as water from hitting the electrical component from a plurality of directions. Thus, the waterproofing effect on the electrical component can be enhanced.

### Supplementary Note 4

In the electrical component protection structure described in Supplementary Note 3, extending directions of at least two wide portions of the plurality of the wide portions may be directions intersecting with each other.

According to this configuration, it is possible to effectively prevent liquid such as water from hitting the electrical component from two different directions.

### Supplementary Note 5

In the electrical component protection structure described in Supplementary Note 3 or 4, an extending direction of at least one wide portion of the plurality of the wide portions and an extending direction of the stay may be directions intersecting with each other.

According to this configuration, it is possible to effectively prevent liquid such as water from hitting the electrical component from two different directions.

### Supplementary Note 6

In the electrical component protection structure described in any one of Supplementary Notes 3 to 5, total longitudinal lengths (L1 to L3) of at least two wide portions of the plurality of the wide portions may be different from each other.

According to this structure, by changing the total length of the wide portion in the longitudinal direction according to the formation position of the wide portion, it is possible to enhance the waterproof effect on the electrical component with the minimum space required. In addition, the weight of the support member can be reduced.

### Supplementary Note 7

In the electrical component protection structure according to any one of Supplementary Notes 1 to 6, the support member may further include a mounting portion (64) to which the stay is mounted by fitting a fitted portion (49), which is a part of the stay.

According to this configuration, the electrical component can be mounted to the mounting target with a simple configuration without providing additional separate members.

### Supplementary Note 8

In the electrical component protection structure described in Supplementary Note 7, the mounting portion may be provided on an adjacent wall portion (74), which is a wall portion of the peripheral wall that is adjacent to the partial wall portion, and the mounting portion may be formed with a fitting hole (76) into which the fitted portion is fitted.

According to this configuration, the electrical component can be attached to the mounting target with a simpler configuration.

### Supplementary Note 9

In the electrical component protection structure described in Supplementary Note 8, the support member may further include a protection portion (66) provided on a side of an opening (78) of the fitting hole of the mounting portion, and the protection portion may cover a portion of the stay that is further outside in the axial direction of the peripheral wall the opening in a state where the fitted portion is fitted into the fitting hole.

According to this structure, the stay or the peripheral member of the stay is displaced to prevent the stay or the peripheral member of the stay from being damaged.

### Supplementary Note 10

In the electrical component protection structure according to any one of Supplementary Notes 1 to 9, the stay may be attached to a vehicle body frame (18) of a vehicle (12), which is a mounting target, and the electrical component may overlap the vehicle body frame in a side view of the vehicle.

According to this configuration, the waterproof effect on the electrical component can be further enhanced.

### Supplementary Note 11

A vehicle of the present disclosure includes the electrical component protection structure according to any one of Supplementary Notes 1 to 10, and an electrical component.

### Supplementary Note 12

The vehicle described in Supplementary Note 11 may further include a harness (38) connected to the electrical component, and a vehicle body frame to which the stay is mounted, wherein the electrical component may overlap the vehicle body frame in a side view of the vehicle, the vehicle body frame may include a central portion (19a) protruding outward in the vehicle width direction and an edge portion (19b) protruding inward in the vehicle width direction, the stay may be mounted to the edge portion of the vehicle body frame, and the harness may be routed between the stay and the central portion of the vehicle body frame.

According to this configuration, the harness is routed in the space created between the stay and the central portion. This prevents the harness from contacting other members without providing any additional member. Moreover, it is possible to prevent, without providing any additional member, the harness from being damaged by contacting flicked stones and obstacles during the traveling of the vehicle.

Although concerning the present disclosure, a detailed description thereof has been presented above, the present disclosure is not necessarily limited to the individual embodiments described above. These embodiments may be subjected to various additions, substitutions, modifications, partial deletions and the like, within a range that does not deviate from the essence and gist of the present disclosure, or the spirit of the present disclosure as derived from the content described in the claims and equivalents thereof. Further, the embodiments can also be implemented together in combination. For example, in the above-described embodiments, the order of each of the operations and the order of each of the processes are illustrated as examples, and the present invention is not necessarily limited to these features. The same also applies to cases in which numerical values or mathematical expressions are used in the description of the aforementioned embodiments.

What is claimed is:

1. An electrical component protection structure comprising:
a support member including a peripheral wall surrounding an electrical component, the support member being configured to support the electrical component; and
a stay connected to the support member and mounted to a mounting target,
wherein
the support member includes a wide portion protruding toward the stay from a partial wall portion that is a wall portion of the peripheral wall that faces the stay.

2. The electrical component protection structure according to claim 1, wherein
the wide portion is provided on the partial wall portion in a manner so that a gap is created between the wide portion and the stay.

3. The electrical component protection structure according to claim 1, wherein
the support member includes a plurality of the wide portions, and
the plurality of the wide portions are provided at different positions of the partial wall portion.

4. The electrical component protection structure according to claim 3, wherein
extending directions of at least two wide portions of the plurality of the wide portions are directions intersecting with each other.

5. The electrical component protection structure according to claim 3, wherein
an extending direction of at least one wide portion of the plurality of the wide portions and an extending direction of the stay are directions intersecting with each other.

6. The electrical component protection structure according to claim 3, wherein
total longitudinal lengths of at least two wide portions of the plurality of the wide portions are different from each other.

7. The electrical component protection structure according to claim 1, wherein
the support member further includes a mounting portion to which the stay is mounted by fitting into the mounting portion a fitted portion that is a part of the stay.

8. The electrical component protection structure according to claim 7, wherein
the mounting portion is provided on an adjacent wall portion that is a wall portion of the peripheral wall that is adjacent to the partial wall portion, and
the mounting portion is formed with a fitting hole into which the fitted portion is fitted.

9. The electrical component protection structure according to claim 8, wherein
the support member further includes a protection portion provided on a side of an opening of the fitting hole of the mounting portion, and
the protection portion covers a portion of the stay that is further outside in an axial direction of the peripheral wall than the opening, in a state where the fitted portion is fitted into the fitting hole.

10. The electrical component protection structure according to claim 1, wherein
the stay is mounted to a vehicle body frame of a vehicle, the vehicle body frame being the mounting target, and
the electrical component overlaps the vehicle body frame in a side view of the vehicle.

11. A vehicle comprising:
the electrical component protection structure according to claim 1; and
the electrical component.

12. The vehicle according to claim 11, further comprising:
a harness connected to the electrical component; and
a vehicle body frame to which the stay is mounted,
wherein
the electrical component overlaps the vehicle body frame in a side view of the vehicle,
the vehicle body frame includes a central portion projecting outward in a vehicle width direction, and an edge portion projecting inward in the vehicle width direction,
the stay is mounted to the edge portion of the vehicle body frame, and
the harness is routed between the stay and the central portion of the vehicle body frame.
